(19) United States
(12) Patent Application Publication
(10) Pub. No.: US 2024/0419208 A1
(43) Pub. Date: Dec. 19, 2024

(54) SIGNAL TRANSMITTING SYSTEM AND SIGNAL TRANSMITTING METHOD

(71) Applicant: Realtek Semiconductor Corp., HsinChu (TW)

(72) Inventor: Chun-Ta Ho, Hsinchu (TW)

(73) Assignee: Realtek Semiconductor Corp., HsinChu (TW)

(21) Appl. No.: 18/743,071

(22) Filed: Jun. 13, 2024

(30) Foreign Application Priority Data
Jun. 15, 2023 (TW) 112122300

(51) Int. Cl. G06F 1/06; H03L 7/08

(52) U.S. Cl. CPC G06F 1/06; H03L 7/08

(57) ABSTRACT

A signal transmitting system comprising: a first transmitting circuit, operating according to a first operation clock signal with a first phase; a second transmitting circuit, operating according to a second operation clock signal with a second phase, wherein the first phase and the second phase are different; and a multi-phase clock signal generating circuit, coupled to the first transmitting circuit and the second transmitting circuit, to generate the first operation clock signal and the second operation clock signal.

### BACKGROUND OF THE INVENTION

### 1. Field of the Invention

The present invention relates to a signal transmitting system and a signal transmitting method, and particularly relates to a signal transmitting system and a signal transmitting method which can reduce power ripple.

### 2. Description of the Prior Art

A conventional signal transmitting system comprises a plurality of transmitting circuits, and each transmitting circuit receives an operation clock signal and operates according to the operation clock signal. These operation clock signals have the same phases, so logic level transitions thereof are performed at the same time. In other words, rising edges or falling edges of the operation clock signals are generated at the same time. However, such mechanism may cause power ripples in the power signal of the entire system, which may affect the operation of the entire signal transmitting system or generate signal noise.

### SUMMARY OF THE INVENTION

One objective of the present invention is to provide a signal transmitting system which can reduce power ripple.

Another objective of the present invention is to provide a signal transmitting system which can reduce power ripple.

One embodiment of the present invention discloses a signal transmitting system comprising: a first transmitting circuit, operating according to a first operation clock signal with a first phase; a second transmitting circuit, operating according to a second operation clock signal with a second phase, wherein the first phase and the second phase are different; and a multi-phase clock signal generating circuit, coupled to the first transmitting circuit and the second transmitting circuit, to generate the first operation clock signal and the second operation clock signal.

Another embodiment of the present invention discloses a signal transmitting system comprising: a plurality of transmitting circuits, configured to respectively receive one of a plurality of operation clock signals with different phases; and a multi-phase clock signal generating circuit, coupled to the transmitting circuits, configured to generate the operation clock signals.

Still another embodiment of the present invention discloses a signal transmitting method, applied to a signal transmitting system, comprising: generating a first operation clock signal with a first phase; generating a second operation clock signal with a second phase, wherein the first phase and the second phase are different; controlling a first transmitting circuit of the signal transmitting system to operate according to the first operation clock signal; and controlling a second transmitting circuit of the signal transmitting system to operate according to the second operation clock signal.

In view of above-mentioned embodiments, different transmitting circuits may operate according to operation clock signals with different phases, so that the operation clock signals do not change logic levels thereof at the same time. By this way, the problem of power supply ripple in the prior art can be improved.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a block diagram illustrating a signal transmitting system according to one embodiment of the present invention.

FIG. 2 is a schematic diagram illustrating operation clock signals of the signal transmitting system in FIG. 1.

FIG. 3, FIG. 4 and FIG. 5 are block diagrams illustrating signal transmitting systems according to different embodiments of the present invention.

FIG. 6 is an exemplary circuit of the PRBS (pseudirandom binary sequence) generator in FIG. 5.

FIG. 7 is a flow chart illustrating a signal transmitting method according to one embodiment of the present invention.

### DETAILED DESCRIPTION

Several embodiments are provided in following descriptions to explain the concept of the present invention. The term “first”, “second”, “third” in following descriptions are only for the purpose of distinguishing different one elements, and do not mean the sequence of the elements. For example, a first device and a second device only mean these devices can have the same structure but are different devices.

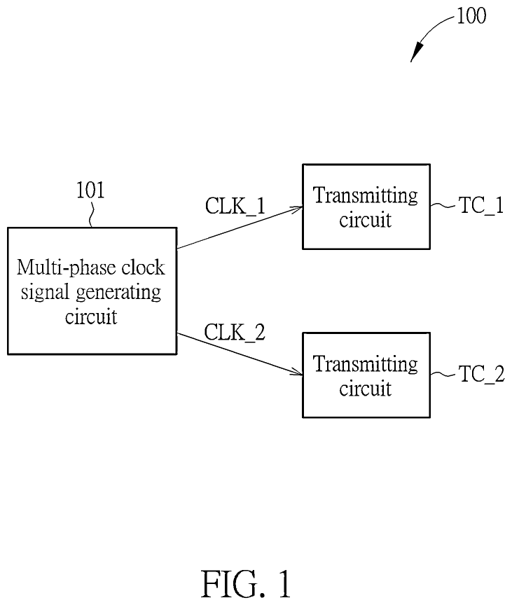

FIG. 1 is a block diagram illustrating a signal transmitting system according to one embodiment of the present invention. As shown in FIG. 1, the signal transmitting system 100 comprises a multi-phase clock signal generating circuit 101, a first transmitting circuit TC_1 and a second transmitting circuit TC_2. The first transmitting circuit TC_1 operates according to a first operation clock signal CLK_1 with a first phase. The second transmitting circuit TC_2 operates according to a second operation clock signal CLK_2 with a second phase, wherein the first phase is different from the second phase. In one embodiment, the first transmitting circuit TC 1 samples data according to the rising or falling edges of the first operation clock signal CLK_1, and the second transmitting circuit TC 2 samples data according to the rising or falling edges of the second operation clock signal CLK_2.

The multi-phase clock signal generating circuit 101 is coupled to the first transmitting circuit TC_1 and the second transmitting circuit TC_2 for generating the first operation clock signal CLK_1 and the second operation clock signal CLK_2. In one embodiment, the first transmitting circuit TC_1 and the second transmitting circuit TC_2 are transmitting circuits for different channels or different lanes. In addition, in one embodiment, the first operation clock signal CLK_1 and the second operation clock signal CLK_2 are respectively received by drivers in the first transmitting circuit TC_1 and the second transmitting circuit TC_2, and the drivers respectively operates according to the first operation clock signal CLK_1 and the second operation clock signal CLK_2. In other words, the drivers respectively operates according to rising edges, falling edges or logic levels of the first operation clock signal CLK_1 and the second operation clock signal CLK_2.

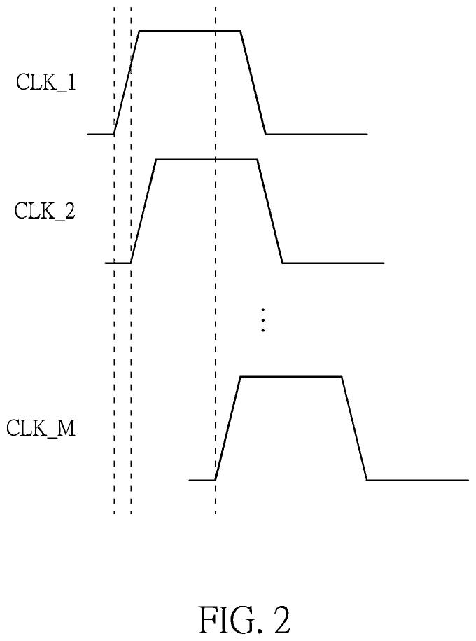

FIG. 2 is a schematic diagram illustrating operation clock signals of the signal transmitting system in FIG. 1. As shown in FIG. 2, the first operation clock signal CLK_1 and the second operation clock signal CLK_2 have different phases. In one embodiment, the first operation clock signal CLK_1 and the second operation clock signal CLK_2 have the same clock frequency and duty cycle, but have different phases. Thereby, the rising and falling edges of the first operation clock signal CLK_1 and the second operation clock signal CLK_2 do not occur at the same time, so that the problem of power supply ripple in the prior art can be improved.

In addition, in the embodiment of FIG. 1, two transmitting circuits are used as examples for explaining. However, the signal transmitting system of the present invention may comprise more than two transmitting circuits. For example, in one embodiment, the signal transmitting system provided by the present invention comprises M transmitting circuits (M>2). In such embodiment, the M operation clock signals used by the M transmitting circuits all have different phases. As shown in FIG. 2, the M operation clock signals CLK_1, CLK_2 . . . . CLK_M all have different phases. In such embodiment, the signal transmitting system provided by the present invention can be simplified as: a signal transmitting system, comprising: a first transmitting circuit, operating according to a first operation clock signal with a first phase; a second transmitting circuit, operating according to a second operation clock signal with a second phase, wherein the first phase and the second phase are different; and a multi-phase clock signal generating circuit, coupled to the first transmitting circuit and the second transmitting circuit, to generate the first operation clock signal and the second operation clock signal. However, it should be noted that the signal transmitting system provided by the present invention is not limited to that all of the operation clock signals used by the transmitting circuits have different phases. It is also possible that the operation clock signals used by some transmitting circuits have different phases, but the operation clock signals used by some transmitting circuits have the same phase. Such architecture can also be used in other embodiments below.

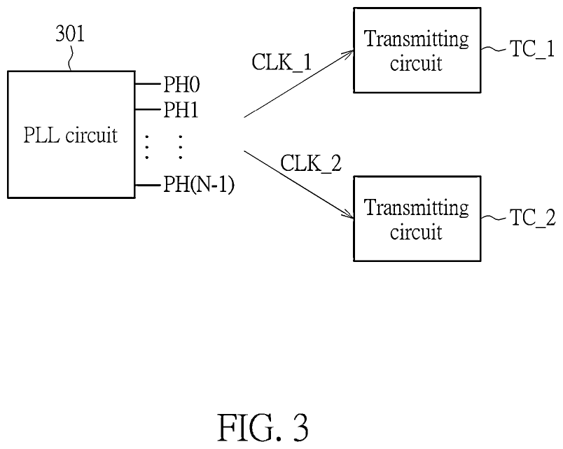

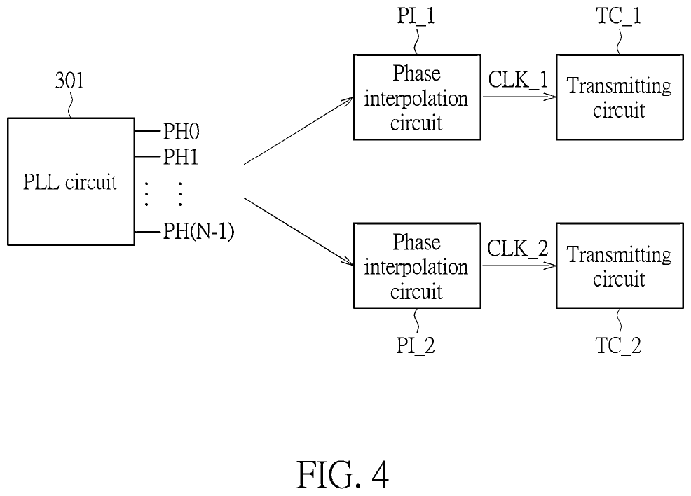

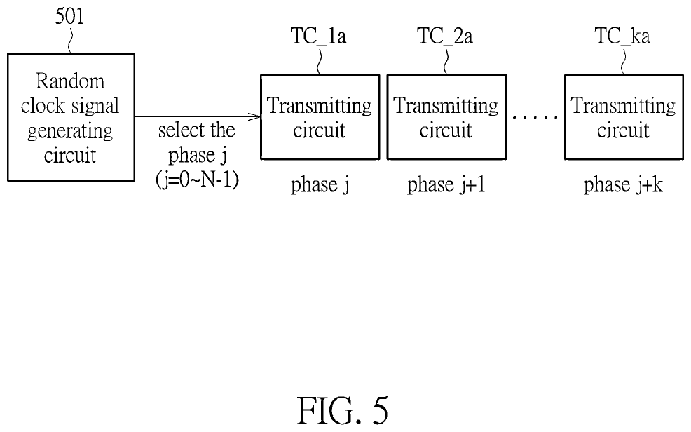

The multi-phase clock signal generating circuit 101 shown in FIG. 1 can be realized by various circuits. FIG. 3, FIG. 4 and FIG. 5 are block diagrams illustrating signal transmitting systems according to different embodiments of the present invention. In the embodiment shown in FIG. 3, the multi-phase clock signal generating circuit 101 is a PLL (phase-locked loop) circuit 301. As shown in FIG. 3, the multi-phase clock signal generating circuit 101 is used to generate clock signals PH0, PH1 . . . . PH (N−1) with different phases, and then two of the clock signals PH0, PH1 . . . . PH (N−1) can be used as the operation clock signals CLK_1, CLK_2.

In the embodiment shown in FIG. 4, the multi-phase clock signal generating circuit 101 comprises a PLL circuit 301, a first phase interpolation circuit PI_1 and a second phase interpolation circuit PI_2. In such embodiment, the clock signals PH0, PH1. PH (N−1) generated by the PLL circuit 301 are used as candidate clock signals. The first phase interpolation circuit PI_1 generates the first operation clock signal CLK_1 according to at least one first candidate clock signal of the candidate clock signals, and the second phase interpolation circuit PI_2 generates the second operation clock signal CLK_2 according to at least one second candidate clock signal of the candidate clock signals. The first phase interpolation circuit PI_1 and the second phase interpolation circuit PI_2 may be realized by various circuits. In one embodiment, the first phase interpolation circuit PI_1 and the second phase interpolation circuit PI_2 have adjustable current sources, and these adjustable current sources can be adjusted to set the phases of the operation clock signals output by the first phase interpolation circuit PI_1 and the second phase interpolation circuit PI_2. Other detail structures of the phase interpolation circuit have been disclosed in the prior art. For example, the US Patent with a patent No. U.S. Pat. No. 8,564,352 discloses the phase interpolation circuit, so detail descriptions thereof are not repeated here.

In the embodiment of FIG. 5, the multi-phase clock signal generating circuit 101 comprises a random clock signal generating circuit 501, which is used to generate random clock signals. That is, generating a plurality of random clock signals with different phases. In one embodiment, the random clock signal generating circuit 501 is a PRBS generator. The PRBS generator is used to randomly generate 0 or 1 within a cycle.

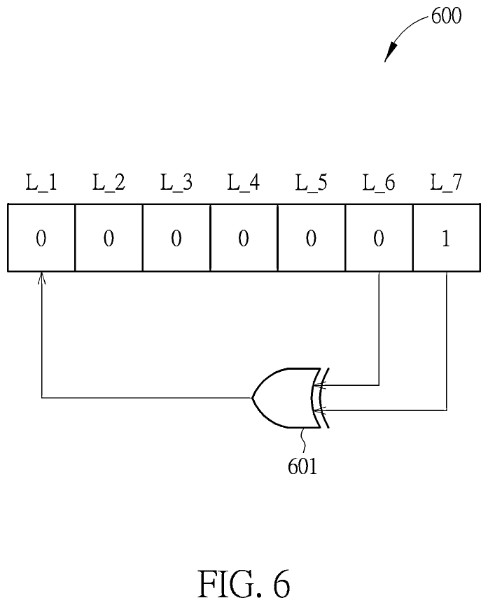

FIG. 6 is an exemplary circuit of the PRBS generator in FIG. 5. In the embodiment of FIG. 6, the random clock signal generating circuit 501 is a LFSR 600 (Linear feedback shift register), which can be used as a PRBS generator. As shown in FIG. 6, the LFSR 600 comprises registers L_1, L_2, L_3, L_4, L_5, L_6 and L_7, which correspond to the equation X7+X6+1=0. The LFSR 600 takes the output linear function as an input, that is, the output is processed by the XOR logic gate 601 as an input, and then shifts the number of bits in the registers L_1, L_2, L_3, L_4, L_5, L_6 and L_7. The initial values in the registers L_1, L_2, L_3, L_4, L_5, L_6 and L_7 are called “seeds”. Take FIG. 6 as an example, the seed is 0000001. Detail operations of the LFSR 600 are well known by persons skilled in the art, thus are omitted for brevity here. Please also note that the PRBS generator may contain structures other than which shown in FIG. 6. Also, in addition to the aforementioned embodiments, the multi-phase clock signal generating circuit 101 may also be other circuits capable of generating clock signals with different phases. For example, the multi-phase clock signal generating circuit 101 can be a delay chain circuit.

Please refer to FIG. 5 again. After the random clock signal generating circuit 501 generates clock signals with different phases, these clock signals may be directly used as operation clock signals for different transmitting circuits. In another embodiment, after selecting one of the clock signals generated by the random clock signal generating circuit 501, the operation clock signals for different transmitting circuits are generated according to the selected clock signal. Taking FIG. 5 as an example, the random clock signal generating circuit 501 generates N clock signals, and the clock signal with phase j among them is selected to generate operation clock signals for different transmitting circuits. In the embodiment shown in FIG. 5, there are K transmitting circuits TC_1a, TC_2a . . . . TC_Ka, and these transmitting circuits respectively using operation clock signals with phase j, phase j+1, phase j+2 . . . phase j+k. Adjacent phases respectively have a predetermined phase difference. For example, the phase j and the phase j+1 have a predetermined phase difference, and phase j+k−1 and phase j+k also have the predetermined phase difference.

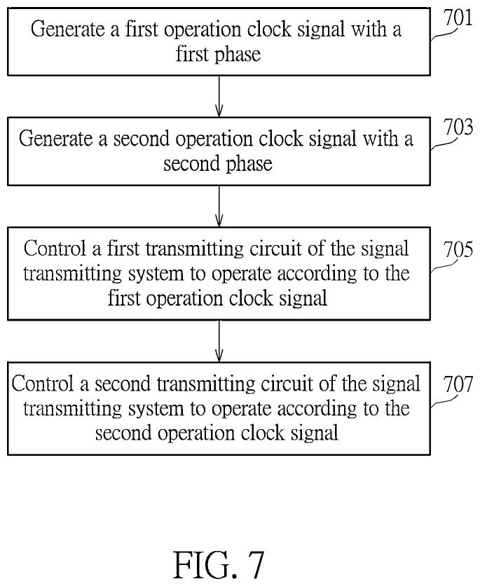

In view of above-mentioned embodiments, a signal transmitting method can be acquired. FIG. 7 is a flow chart illustrating a signal transmitting method according to one embodiment of the present invention, which is used in a signal transmitting system and comprises following steps:

### Step 701

Generate a first operation clock signal with a first phase (e.g., the first operation clock signal CLK_1 shown in FIG. 2).

### Step 703

Generate a second operation clock signal with a second phase (e.g., the second operation clock signal CLK_2 shown in FIG. 2). The first phase and the second phase are different.

### Step 705

Control a first transmitting circuit (e.g., the first transmitting circuit TC_1 shown in FIG. 1) of the signal transmitting system to operate according to the first operation clock signal.

### Step 707

Control a second transmitting circuit (such as the second transmitting circuit TC_2 shown in FIG. 1) of the signal transmitting system to operate according to the second operation clock signal.

In view of above-mentioned embodiments, different transmitting circuits may operate according to operation clock signals with different phases, so that the operation clock signals do not change logic levels thereof at the same time. By this way, the problem of power supply ripple in the prior art can be improved.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A signal transmitting system, comprising:
a first transmitting circuit, operating according to a first operation clock signal with a first phase;
a second transmitting circuit, operating according to a second operation clock signal with a second phase, wherein the first phase and the second phase are different; and
a multi-phase clock signal generating circuit, coupled to the first transmitting circuit and the second transmitting circuit, to generate the first operation clock signal and the second operation clock signal.

2. The signal transmitting system of claim 1, wherein the first transmitting circuit and the second transmitting circuit are transmitting circuits for different channels or different lanes.

3. The signal transmitting system of claim 1, wherein drivers of the first transmitting circuit and the second transmitting circuit respectively receive the first operation clock signal and the second operation clock signal, and respectively operates according to the first operation clock signal and the second operation clock signal.

4. The signal transmitting system of claim 1, wherein the multi-phase clock signal generating circuit is a PLL (Phase Locked Loop) circuit.

5. The signal transmitting system of claim 1, wherein the multi-phase clock signal generating circuit comprises:
a PLL circuit, configured to generate a plurality of candidate clock signals with different phases;
a first phase interpolation circuit, coupled to the PLL circuit and the first transmitting circuit, configured to generate the first operation clock signal according to at least one first candidate clock signal of the candidate clock signals;
a second phase interpolation circuit, coupled to the PLL circuit and the second transmitting circuit, configured to generate the second operation clock signal according to at least one second candidate clock signal of the candidate clock signals.

6. The signal transmitting system of claim 1, wherein the multi-phase clock signal generating circuit comprises a random clock signal generating circuit.

7. The signal transmitting system of claim 6, wherein the random clock signal generating circuit is a PRBS (pseudirandom binary sequence) generator.

8. The signal transmitting system of claim 1, wherein the multi-phase clock signal generating circuit is a delay line circuit.

9. A signal transmitting system, comprising:
a plurality of transmitting circuits, configured to respectively receive one of a plurality of operation clock signals with different phases; and
a multi-phase clock signal generating circuit, coupled to the transmitting circuits, configured to generate the operation clock signals.

10. The signal transmitting system of claim 9, wherein the transmitting circuits are for different channels or different lanes.

11. The signal transmitting system of claim 9, wherein drivers of the transmitting circuits respectively receive the operation clock signals.

12. The signal transmitting system of claim 9, wherein the multi-phase clock signal generating circuit is a PLL circuit.

13. The signal transmitting system of claim 9, wherein the multi-phase clock signal generating circuit comprises:
a PLL circuit, configured to generate a plurality of candidate clock signals with different phases;
a plurality of phase interpolation circuit, coupled to the PLL circuit, configured to generate the operation clock signals according to the candidate clock signals.

14. The signal transmitting system of claim 9, wherein the multi-phase clock signal generating circuit comprises a random clock signal generating circuit.

15. The signal transmitting system of claim 14, wherein the random clock signal generating circuit is a PRBS (pseudirandom binary sequence) generator.

16. The signal transmitting system of claim 9, wherein the multi-phase clock signal generating circuit is a delay line circuit.

17. The signal transmitting system of claim 9, wherein a number of the transmitting circuits is larger than 2.

18. A signal transmitting method, applied to a signal transmitting system, comprising:
generating a first operation clock signal with a first phase;
generating a second operation clock signal with a second phase, wherein the first phase and the second phase are different;
controlling a first transmitting circuit of the signal transmitting system to operate according to the first operation clock signal; and
controlling a second transmitting circuit of the signal transmitting system to operate according to the second operation clock signal.

19. The signal transmitting method of claim 18, wherein the step of generating the first operation clock signal and the second operation clock signal comprises:
using a PLL circuit to generate a plurality of candidate clock signals with different phases;
using a first phase interpolation circuit to generate the first operation clock signal according to at least one first candidate clock signal of the candidate clock signals; and
using a second phase interpolation circuit to generate the second operation clock signal according to at least one second candidate clock signal of the candidate clock signals.

20. The signal transmitting method of claim 18, further comprising:
using a random clock signal generating circuit to generate the first operation clock signal and the second operation clock signal.
